(19) United States
(12) Patent Application Publication
(10) Pub. No.: US 2007/0188246 A1
(43) Pub. Date: Aug. 16, 2007

(54) Oscillator operable in various frequencies

(76) Inventors: Yun-woo Lee, Seoul (KR); Kyu-jong Cho, Suwon-si (KR); Hye-jin Lee, Jeonju-si (KR)

Correspondence Address: MILLS & ONELLO LLP, ELEVEN BEACON STREET, SUITE 605, BOSTON, MA, 02108, US

(21) Appl. No.: 11/698,425

(22) Filed: Jan. 26, 2007

(30) Foreign Application Priority Data
Jan. 26, 2006 (KR) 10-2006-0008470

(51) Int. Cl. H03L 7/00

(52) U.S. Cl. 331/16

(57) ABSTRACT

An oscillator operable in various frequencies includes an oscillation unit generating a sine wave having a predetermined oscillation frequency, a feedback unit feeding the sine wave back to the oscillation unit, and a frequency control unit controlling an operating frequency of the feedback unit by controlling an amount of current flowing through the feedback unit in response to a frequency control signal. The oscillator can operate in various frequencies by controlling the operating frequency thereof. Consequently, the oscillator can sufficiently secure itself against a power noise margin.

### BACKGROUND OF THE INVENTION

This application claims the priority of Korean Patent Application No. 10-2006-0008470, filed on Jan. 26, 2006, in the Korean Intellectual Property Office, the contents of which are incorporated herein in their entirety by reference.

1. Field of the Invention

The present invention relates to an oscillator, and more particularly, to an oscillator operable in various frequencies by controlling an operating frequency thereof.

2. Description of the Related Art

Conventional oscillators used in semiconductor devices include external cells which generate oscillating signals and internal cells which input the oscillating signals generated by the external cells to the semiconductor devices.

The external cells include oscillation devices which generate sine waves having a predetermined wavelength or frequency. The oscillation devices are formed of materials different from those of the semiconductor devices implemented on silicon substrates. Therefore, the external cells, in particular, the oscillation devices, may be disposed outside the semiconductor devices. The internal cells and the semiconductor devices may be implemented on the silicon substrates.

FIG. 1 is a circuit diagram of a conventional oscillator 100 using a crystal oscillation device XTAL. Referring to FIG. 1, the oscillator 100 includes an external cell 120 and an internal cell 110.

The external cell 120 includes first and second capacitors C1 and C2, a resistor R, and the oscillation device XTAL. The oscillation device XTAL generates a sine wave having a predetermined wavelength in response to a voltage applied to both ends of the oscillation device XTAL. The resistor R and the first and second capacitors C1 and C2 ensure that voltage applied to both ends of the oscillation device XTAL is stable.

A buffer unit (not shown), which may be included in a semiconductor device (not shown), buffers the sine wave generated by the oscillation device XTAL and inputs the buffered sine wave to the semiconductor device.

The entire external cell 120 may be disposed outside the semiconductor device. Alternatively, the oscillation device XTAL or the oscillation device XTAL and the first and second capacitors C1 and C2 may be disposed outside the semiconductor device.

The internal cell 110 includes the buffer unit, buffering the sine wave generated by the oscillation device XTAL of the external cell 120 and inputting the buffered sine wave to the semiconductor device, and an inverter INV inverting the sine wave and feeding the inverted sine wave back to the external cell 120.

In this way, the oscillation device XTAL disposed outside the semiconductor device generates sine waves in a stable manner. Hence, the conventional oscillator 100 exhibits high frequency stability.

However, since the internal cell 110 is included in the semiconductor device, its operating frequency is fixed. Consequently, the oscillation frequency of the internal cell 110 in the conventional oscillator 100 cannot be varied and the internal cell 110 operates at one frequency. Therefore, an oscillator operable in various frequencies is required.

### SUMMARY OF THE INVENTION

The present invention provides an oscillator operable in various frequencies.

According to an aspect of the present invention, there is provided an oscillator comprising: an oscillation unit generating a sine wave having a predetermined oscillation frequency; a feedback unit feeding the sine wave back to the oscillation unit; and a frequency control unit controlling an operating frequency of the feedback unit by controlling an amount of current flowing through the feedback unit in response to a frequency control signal.

In one embodiment, the frequency control unit controls the amount of current such that the operating frequency matches the oscillation frequency. The frequency control unit can include a current source sinking current from the feedback unit in response to the frequency control signal. In one embodiment, the frequency control unit is an NMOS transistor.

The feedback unit can include an inversion circuit inverting the sine wave and outputting a square wave.

In one embodiment, the oscillator further includes a buffer unit buffering and outputting the sine wave.

In one embodiment, the oscillator further includes an input control unit controlling an input of the sine wave to the feedback unit in response to an oscillation enable signal.

According to another aspect of the present invention, there is provided an oscillator comprising: an oscillation unit generating a sine wave having a predetermined oscillation frequency; a feedback unit inverting the sine wave, generating a square wave, and feeding the square wave back to the oscillation unit; a frequency control unit controlling an operating frequency of the feedback unit by controlling an amount of current flowing through the feedback unit in response to a frequency control signal; and a buffer unit buffering and outputting the square wave.

In one embodiment, the frequency control unit controls the amount of current such that the operating frequency matches the oscillation frequency.

The frequency control unit can include a current source sinking current from the feedback unit in response to the frequency control signal. In one embodiment, the frequency control unit is an NMOS transistor.

In one embodiment, the feedback unit comprises an inversion circuit inverting the sine wave and outputting the square wave.

In one embodiment, the oscillator further includes an input control unit controlling an input of the sine wave to the feedback unit in response to an oscillation enable signal.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1 is a circuit diagram of a conventional oscillator.

FIG. 2 is a circuit diagram of an internal cell of an oscillator.

FIG. 3 is a circuit diagram of an internal cell of an oscillator according to an embodiment of the present invention.

FIG. 4 is a circuit diagram of an internal cell of an oscillator according to another embodiment of the present invention.

FIG. 5 is a detailed circuit diagram of a feedback unit and a frequency control unit included in the oscillator of FIG. 4.

FIG. 6 is an input/output waveform diagram of the feedback unit included in the oscillator of FIG. 4 according to an embodiment of the present invention.

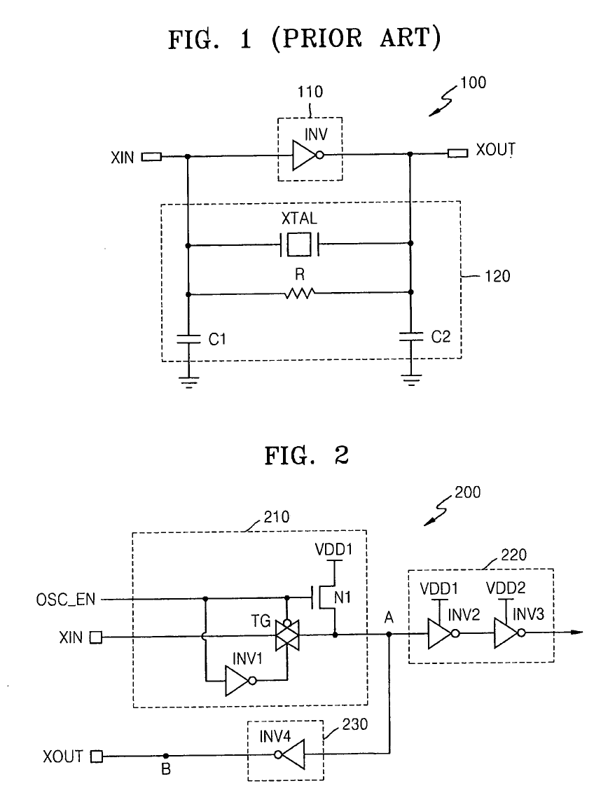

### DETAILED DESCRIPTION OF PREFERRED EMBODIMENTS OF THE INVENTION

FIG. 2 is a circuit diagram of an internal cell of an oscillator 200. The internal cell is part of the oscillator 200 implemented in a semiconductor device (not shown). The oscillator 200 includes an oscillation unit (or an external cell) (not shown) having an oscillation device (not shown) that oscillates and a feedback unit 230. The oscillator 200 may further include a buffer unit 220 and/or an input control unit 210. The oscillation unit (not shown) is connected between a terminal XIN and a terminal XOUT.

A sine wave generated by the oscillation device has a predetermined oscillation frequency and is input to the semiconductor device via the terminal XIN. The semiconductor device converts the sine wave into a square wave and uses the square wave as a clock.

The feedback unit 230 feeds the sine wave generated by the oscillation unit back to the oscillation unit. As illustrated in FIG. 2, the feedback unit 230 may be a fourth inversion circuit INV4.

When the sine wave is inverted by the feedback unit 230 and fed back to the oscillation unit, the oscillation device included in the oscillation unit generates a sine wave based on the received sine wave. Sine waves having a predetermined oscillation frequency are continuously generated through these oscillation and feedback operations.

The buffer unit 220 buffers the sine wave having the predetermined oscillation frequency and inputs the sine wave to the semiconductor device. The buffer unit 220 includes a second inversion circuit INV2 using a first voltage source VDD1 and a third inversion circuit INV3 using a second voltage source VDD2. The second and third inversion circuits INV2 and INV3 convert the sine wave into a square wave.

Since the second and third inversion circuits INV2 and INV3 use different voltage sources, that is, the first and second voltage sources VDD1 and VDD2, they not only can convert the sine wave into the square wave but also shift a level of the square wave.

The input control unit 210, which is an optional circuit of the oscillator 200, controls the operation of the oscillator 200. The input control unit 210 allows the sine wave input to the terminal XIN to be transmitted to a first node A or blocks the sine wave from being sent to the first node A in response to an oscillation enable signal OSC_EN. In so doing, the input control unit 210 controls the oscillator 200 when the oscillator 200 inputs a sine wave to the semiconductor device.

The input control unit 210 includes a first inversion circuit INV1, a transmission gate TG, and an NMOS transistor N1. When the oscillation enable signal OSC_EN is in a first state (logic high), signals in a second state (logic low) are input to a control terminal of the transmission gate TG. Consequently, the transmission gate TG is blocked, thereby blocking the sine wave from being input to the first node A. Accordingly, the oscillator 200 stops operating.

At this time, the NMOS transistor N1 is turned on in response to the oscillation enable signal OSC_EN in a high level. The first node A is put in a high level and the second node B is put in a low level. Since the signals fed back to the oscillation unit are in the low level, the oscillation device included in the oscillation unit does not oscillate.

When the oscillation enable signal OSC_EN is in the low level, the NMOS transistor N1 is turned off. In addition, since signals in the high level are input to the control terminal of the transmission gate TG, the transmission gate TG inputs the sine wave received from the oscillation unit to the first node A. Accordingly, the oscillator 200 oscillates.

As described above, the oscillator 200 inputs the sine wave generated by the oscillation unit to the semiconductor device and, at the same time, feeds the sine wave back to the oscillation unit so that the oscillation unit can continuously oscillate.

Since the feedback unit 230 included in the oscillator 200 of FIG. 2 operates at constant speed, signals having a constant frequency are fed back to the oscillation unit. That is, the oscillation frequency of the oscillator 200 of FIG. 2 is fixed. Therefore, the oscillator 200 may have high frequency stability but its oscillation frequency cannot be varied.

In this regard, it is required to change the oscillation frequency of the oscillator 200 by varying the operating speed, that is, operating frequency, of the feedback unit 230. If the operating frequency of the feedback unit 230 can be varied, the oscillation frequency of the oscillator 200 can also be varied using an oscillation device that can handle the varying operating frequency of the feedback unit 230.

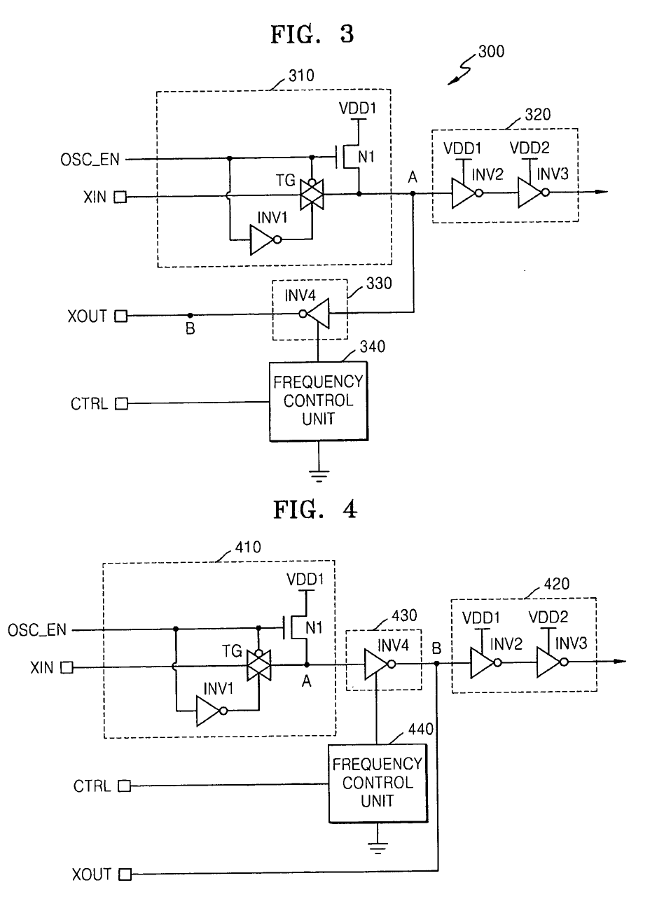

FIG. 3 is a circuit diagram of an internal cell of an oscillator 300 according to an embodiment of the present invention. Referring to FIG. 3, the oscillator 300 includes an oscillation unit (not shown), a feedback unit 330, and a frequency control unit 340. The oscillator 300 may further include an input control unit 310 and/or a buffer unit 320.

The structures and operations of the oscillation unit, the input control unit 310, the buffer unit 320, and the feedback unit 330 of FIG. 3 are identical to those of the oscillation unit, the input control unit 210, the buffer unit 220, and the feedback unit 230 of FIG. 2. Therefore, the following descriptions of FIG. 3 will be focused on the structure and operation of the frequency control unit 340 and interaction between the frequency control unit 340 and the feedback unit 330.

The frequency control unit 340 controls the amount of current flowing through the feedback unit 330 in response to a frequency control signal CTRL, thereby controlling the operating speed, that is, operating frequency, of the feedback unit 330. In the present embodiment, the frequency control unit 340 controls the amount of current flowing through the feedback unit 330 such that the operating frequency of the feedback unit 330 matches the oscillation frequency of an oscillation device (not shown) included in the oscillation unit.

For example, the frequency control unit 340 may sink current from the feedback unit 330 in response to the frequency control signal CTRL to control the amount of current flowing through the feedback unit 330.

As the amount of current sunk by the frequency control unit 340 becomes larger, a smaller amount of current flows through the feedback unit 330. Accordingly, the operating speed (operating frequency) of the feedback unit 330 is reduced. Conversely, as the amount of current sunk by the frequency control unit 340 becomes smaller, a larger amount of current flows through the feedback unit 330. Accordingly, the operating speed (operating frequency) of the feedback unit 330 is increased.

In this case, the frequency control unit 340 may include a current source for sinking current in response to the frequency control signal CTRL.

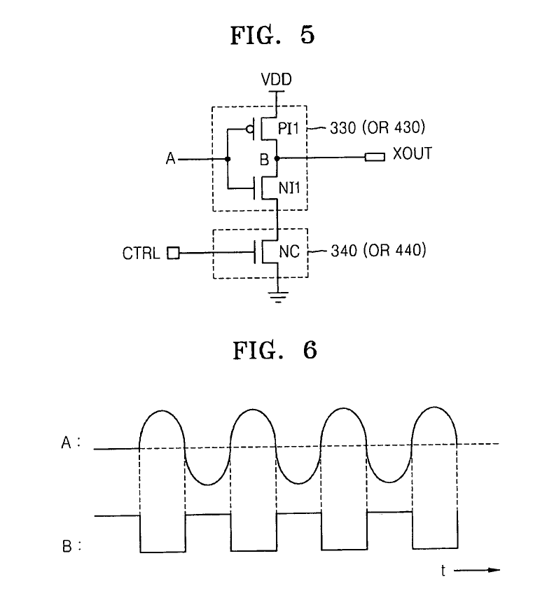

The operation of the frequency control unit 340 will now be described in detail with reference to FIG. 5. FIG. 5 is an exemplary circuit, and it would be understood by those of ordinary skill in the art that the present embodiment of the invention is not limited to the circuit of FIG. 5.

FIG. 5 is a detailed circuit diagram of the feedback unit 330 and the frequency control unit 340 included in the oscillator 300 of FIG. 4. Referring to FIG. 5, the feedback unit 330 is a basic inversion circuit having a PMOS transistor PI1 and an NMOS transistor NI1 connected in series. Gates of the PMOS transistor PI1 and the NMOS transistor NI1 are connected to the first node A, and sine waves generated by the oscillation unit are input.

The frequency control circuit 340 may be or may include an NMOS transistor NC. The NMOS transistor NC is connected to the feedback unit 330 (that is, the NMOS transistor N11) in series. The frequency control signal CTRL is transmitted to a gate of the NMOS transistor NC and thus controls the operation of the NMOS transistor NC.

Current flowing through the NMOS transistor NC is proportional to a voltage level of the frequency control signal CTRL transmitted to the gate of the NMOS transistor NC. Therefore, the voltage level of the frequency control signal CTRL can be controlled to control the current flowing through the NMOS transistor NC.

That is, the frequency control circuit 340 controls the amount of current flowing from the NMOS transistor NC to a ground source, that is, the amount of current sunk from the feedback unit 330, in response to the frequency control signal CTRL. Accordingly, the amount of current flowing through the feedback unit 330 is controlled. In so doing, the operating speed (operating frequency) of the feedback unit 330 can be controlled.

FIG. 4 is a circuit diagram of an internal cell of an oscillator 400 according to another embodiment of the present invention. The oscillator 400 includes an oscillation unit (not shown), a feedback unit 430, a frequency control unit 440, and a buffer unit 420. The oscillator 400 may further include an input control unit 410.

The oscillator 400 of FIG. 4 is identical to the oscillator 300 of FIG. 3 except that the buffer unit 420 included in the oscillator 400 of FIG. 4 is connected to a second node B, not the first node A. The operation of the buffer unit 420 will now be described with reference to FIGS. 4 and 6.

FIG. 6 is an input/output waveform diagram of the feedback unit 430 included in the oscillator 400 according to an embodiment of the present invention. Waveform A in FIG. 6 is a waveform of the first node A, and Waveform B of FIG. 6 is a waveform of the second node B. Referring to FIG. 6, a sine wave of the first node A is inverted by the feedback unit 430 and is output as a square wave from the second node B.

The buffer unit 320 of the oscillator 300 of FIG. 3 includes the second and third inversion circuits INV2 and INV3 which invert, buffer, and output the sine wave of the first node A.

When the sine wave has a low frequency, noise may induce oscillations in a signal level of the sine wave. In this case, the second inversion circuit INV2 of the buffer unit 320 may fail to accurately operate due to the oscillated signal level of the sine wave.

More specifically, the second inversion circuit INV2 inverts the state of the sine wave based on an intermediate level of the sine wave (for example, a level between a high level and a low level). When noise is present, the intermediate level of the sine wave having a low frequency is oscillated by the noise. In this case, the second inversion circuit INV2 may continuously perform an inaccurate inversion operation according to the oscillated intermediate level. That is, the oscillator 300 is vulnerable to a power noise margin.

The oscillator 400 of FIG. 4 can be used to overcome this problem of the oscillator 300 of FIG. 3. The buffer unit 420 of the oscillator 400 of FIG. 4 inverts and buffers the square wave of the second node B instead of the sine wave of the first node A. Since the intermediate level of the square wave is not oscillated by noise, the oscillator 400 is strongly resistant to the power noise margin.

As described above, an oscillator according to an embodiment of the present invention can operate at various frequencies by controlling its operating frequency. Consequently, the oscillator can sufficiently secure itself against a power noise margin.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An oscillator, comprising:
an oscillation unit generating a sine wave having a predetermined oscillation frequency;
a feedback unit feeding the sine wave back to the oscillation unit; and
a frequency control unit controlling an operating frequency of the feedback unit by controlling an amount of current flowing through the feedback unit in response to a frequency control signal.

2. The oscillator of claim 1, wherein the frequency control unit controls the amount of current such that the operating frequency matches the oscillation frequency.

3. The oscillator of claim 2, wherein the frequency control unit comprises a current source sinking current from the feedback unit in response to the frequency control signal.

4. The oscillator of claim 3, wherein the frequency control unit is an NMOS transistor.

5. The oscillator of claim 1, wherein the feedback unit comprises an inversion circuit inverting the sine wave and outputting a square wave.

6. The oscillator of claim 1, further comprising a buffer unit buffering and outputting the sine wave.

7. The oscillator of claim 1, further comprising an input control unit controlling an input of the sine wave to the feedback unit in response to an oscillation enable signal.

8. An oscillator, comprising:
an oscillation unit generating a sine wave having a predetermined oscillation frequency;
a feedback unit inverting the sine wave, generating a square wave, and feeding the square wave back to the oscillation unit;
a frequency control unit controlling an operating frequency of the feedback unit by controlling an amount of current flowing through the feedback unit in response to a frequency control signal; and
a buffer unit buffering and outputting the square wave.

9. The oscillator of claim 8, wherein the frequency control unit controls the amount of current such that the operating frequency matches the oscillation frequency.

10. The oscillator of claim 9, wherein the frequency control unit comprises a current source sinking current from the feedback unit in response to the frequency control signal.

11. The oscillator of claim 10, wherein the frequency control unit is an NMOS transistor.

12. The oscillator of claim 8, wherein the feedback unit comprises an inversion circuit inverting the sine wave and outputting the square wave.

13. The oscillator of claim 8, further comprising an input control unit controlling an input of the sine wave to the feedback unit in response to an oscillation enable signal.
